(19) United States
(12) Patent Application Publication
(10) Pub. No.: US 2012/0327319 A1
(43) Pub. Date: Dec. 27, 2012

(54) LIQUID CRYSTAL DISPLAY DEVICE, AND METHOD FOR PRODUCING SAME

(75) Inventors: Toshiki Saitoh, Osaka (JP); Kenji Ikeda, Osaka (JP)

(73) Assignee: SHARP KABUSHIKI KAISHA, Osaka (JP)

(21) Appl. No.: 13/582,815

(22) PCT Filed: Jan. 19, 2011
(86) PCT No.: PCT/JP2011/050834

§ 371 Date: Sep. 5, 2012

(30) Foreign Application Priority Data
Mar. 10, 2010 (JP) 2010-052496

(51) Int. Cl. G02F 1/133; H05K 13/00

(52) U.S. Cl. 349/33; 29/592.1

(57) ABSTRACT

Provided is a high-quality liquid crystal display device in which an electronic component and a flexible printed circuit board are simultaneously mounted onto a liquid crystal panel and the electronic component and the like are prevented from corroding. The liquid crystal display device is provided with a liquid crystal display panel (10), at least one electronic component (40) mounted on the liquid crystal display panel in a peripheral portion, and a flexible printed circuit board (50) disposed in the outer circumferential portion of the electronic component in the peripheral edge portion of the liquid crystal display panel. An anisotropic conductive resin (70), which is formed by dispersing and mixing conductive particles (75) in an insulating resin, is integrally disposed on a region that at least covers a mounting area of the electronic component to a mounting area of the flexible printed circuit board in the outer edge portion of the liquid crystal display panel. The electronic component and the flexible printed circuit board are electrically connected to the liquid crystal display panel, respectively, with the anisotropic conductive resin therebetween. The side surface section in the periphery of the electronic component is covered with the anisotropic conductive resin.

### TECHNICAL FIELD

The present invention relates to a liquid crystal display device having a liquid crystal display panel on which an electronic component is mounted, and to a method of manufacturing same.

The present application claims priority to Patent Application No. 2010-052496 filed in Japan on Mar. 10, 2010. The entire contents of which are hereby incorporated by reference.

### BACKGROUND ART

Electronic products provided with liquid crystal display devices, in other words, electronic products provided with liquid crystal display panels (liquid crystal panels) serving as display units for displaying a picture image and a video image for users, have been used in a variety of fields. In compact mobile game consoles, notebook computers, or mobile phones, for example, the liquid crystal display panels have been used as the units for displaying an image.

Such a liquid crystal panel is configured to have a pair of substrates (typically, an array substrate and a color filter substrate that is disposed to face the array substrate) and a liquid crystal material sealed therebetween, which is thereby held as a liquid crystal layer.

For a method of mounting an electronic component (a driver IC, for example) that supplies signals for driving the liquid crystal panel onto the liquid crystal panel (typically, on the array substrate), the COG (Chip on Glass) assembly can be employed, for example. Conventionally, as shown in FIG. 11, on prescribed locations of wiring lines 580 and 585 patterned and formed on a liquid crystal panel 510 (typically, an array substrate 530), an anisotropic conductive film (ACF) 600 is attached in advance, and a driver IC 540 and the wiring lines 580 and 585 are electrically connected through the ACF 600. On a printed circuit board 560, circuits (controllers) for controlling the driver IC 540 and the like are mounted. The printed circuit board 560 is attached to a flexible printed circuit board (FPC) 550. Part of the FPC 550 is electrically connected to the wiring line 585 on the liquid crystal panel 510 through an ACF 650. Patent Document 1, for example, describes an example of such COG assembly.

### RELATED ART DOCUMENT

### Patent Document

Patent Document 1: Japanese Patent Application Laid-Open Publication No. 2005-86145

### SUMMARY OF THE INVENTION

### Problems to be Solved by the Invention

In a process of attaching the ACFs 600 and 650 to the respective prescribed locations of the wiring lines 580 and 585 that are patterned and formed on the liquid crystal panel 510 (array substrate 530), the ACF 600 for the driver IC and the ACF 650 for the FPC need to be attached separately on the respective prescribed locations. Further, in view of accuracy in attaching the ACFs 600 and 650, a distance between an image display region 515 of the liquid crystal panel 510 and the driver IC 540 and a distance between the driver IC 540 and the FPC 550 need to be far enough. This may cause difficulty in reducing the size of the liquid crystal display device. Also, respective connecting portions of the driver IC 540 and the FPC 550 and peripheral terminal portions thereof may be covered with a resin to prevent possible corrosion and the like that may occur due to humidity and the like at these portions. In this case, the process may become complex, thereby increasing cost.

The present invention was made to solve the conventional problems described above, and aims at providing a high-quality liquid crystal display device that allows an electronic component and a flexible printed circuit board to be mounted simultaneously on a liquid crystal panel thereof and that can prevent corrosion of the electronic component and the like, and providing a technique of manufacturing such a liquid crystal display device.

### Means for Solving the Problems

In order to achieve the above objective, the present invention provides a liquid crystal display device, including: a liquid crystal display panel (liquid crystal panel); at least one electronic component mounted on the liquid crystal display panel in a peripheral edge portion of the panel; and a flexible printed circuit board disposed in the peripheral portion of the liquid crystal display panel on an outer side with respect to the electronic component. In the liquid crystal display device disclosed herein, on the peripheral portion of the liquid crystal display panel, an anisotropic conductive resin made of an insulating resin having conductive particles dispersed and mixed therein is integrally provided (i.e., without having breaks anywhere) on a region that at least covers a mounting area of the electronic component to a mounting area of the flexible printed circuit board. The electronic component and the flexible printed circuit board are electrically connected, respectively, to the liquid crystal display panel through the anisotropic conductive resin. A side surface section in the periphery of the electronic component is covered with the anisotropic conductive resin.

In the liquid crystal display device provided by the present invention, the electronic component and the flexible printed circuit board are electronically connected, respectively, to the liquid crystal display panel (typically, to wiring lines patterned and formed on the array substrate) through the anisotropic conductive resin that is integrally provided at least from the mounting area of the electronic component to the mounting area of the flexible printed circuit board. Also, the side surface of the electronic component is covered with the anisotropic conductive resin. Therefore, with the anisotropic conductive resin that is integrally provided, the electronic component and the flexible printed circuit board can be mounted simultaneously on the liquid crystal display panel, and respective connecting portions of the electronic component and the flexible printed circuit board and the electronic component itself can be prevented from corroding due to humidity or the like. An anisotropic conductive resin that contains a photocurable resin and conductive particles is particularly preferable.

According to a preferred embodiment of the liquid crystal display device disclosed herein, the anisotropic conductive resin that is integrally provided has a portion that is further integrally formed to extend beyond the mounting area of the flexible printed circuit board and protrude outwardly from the outer edge of the liquid crystal display panel. By the resin protruding outwardly from the outer edge, the outer edge of the panel and a portion of the flexible printed circuit board that protrudes outwardly from the outer edge of the panel are fixed to each other.

According to this configuration, by the anisotropic conductive resin that is integrally provided, adhesion strength between the flexible printed circuit board and the liquid crystal display panel (array substrate) at the outer edge of the liquid crystal display panel can be further increased.

According to a preferred embodiment of the liquid crystal display device disclosed herein, the electronic component and the flexible printed circuit board have substantially no anisotropic conductive resin on surfaces opposite to respective portions thereof that are electrically connected to the liquid crystal display panel.

According to this configuration, heat released from the electronic component and the flexible printed circuit board to the air is not blocked. Therefore, damage to the component due to an increase in temperature of the electronic component and the flexible printed circuit board can be prevented.

Another aspect of the present invention provides a method of manufacturing a liquid crystal display device that includes: a liquid crystal display panel; at least one electronic component mounted on the liquid crystal display panel in a peripheral portion of the panel; and a flexible printed circuit board disposed in the peripheral portion of the panel on an outer side with respect to the electric component. The method of manufacturing the liquid crystal display device disclosed herein includes: applying an anisotropic conductive material made of an insulating resin material having conductive particles dispersed and mixed therein continuously on a region in the peripheral portion of the liquid crystal display panel that covers at least the mounting area of the electronic component to the mounting area of the flexible printed circuit board; placing the electronic component on the mounting area of the electronic component in a region where the anisotropic conductive material is continuously applied such that a side surface section in a periphery of the electronic component is covered with the anisotropic conductive material, and disposing the flexible printed circuit board on the mounting area of the flexible printed circuit board, which is located a prescribed distance away from a location where the electronic component is placed in a direction toward an outer circumference; and curing the anisotropic conductive material while applying a prescribed pressing force on the electronic component and the flexible printed circuit board in a direction toward the panel.

In the method of manufacturing the liquid crystal display device in the present invention, the anisotropic conductive material is continuously applied in advance on a region in the peripheral portion of the liquid crystal display panel, which covers at least the mounting area of the electronic component to the mounting area of the flexible printed circuit board. Next, after the electronic component is placed on the mounting area of the electronic component on the anisotropic conductive material such that the side surface section in the periphery of the electronic component is covered therewith, and part of the flexible printed circuit board is disposed on the mounting area of the flexible printed circuit board on the material, the anisotropic conductive material is cured. Therefore, the electronic component and the flexible printed circuit board can be mounted on (electrically connected to) the liquid crystal display panel, and the corrosion of the respective connecting portions of the electronic component and the flexible printed circuit board and the electronic component itself due to humidity or the like can be prevented with a fewer manufacturing steps as compared to the conventional manufacturing method.

In the method of manufacturing the liquid crystal display device disclosed herein, the anisotropic conductive material may be further applied in the amount that allows part of the anisotropic conductive material to extend beyond the mounting area of the flexible printed circuit board and to protrude from the outer edge of the panel when the flexible printed circuit board is placed; and in the curing step, the anisotropic conductive material that protrudes from the outer edge of the panel maybe cured, thereby fixing the flexible printed circuit board and the outer edge of the panel to each other.

According to this configuration, by curing the anisotropic conductive material, the electronic component and the flexible printed circuit board are electrically connected, respectively, to the liquid crystal display panel, and at the same time, the flexible printed circuit board and the liquid crystal display panel (typically, the outer edge of the panel) are fixed to each other. This way, the adhesion strength between the board and the panel at the outer edge of the panel can be further increased.

In the method of manufacturing the liquid crystal display device disclosed herein, in the curing step, the pressing force is applied by pressing respective top surfaces of the electronic component and the flexible printed circuit board (typically, an opposite surface of a surface that is connected to the liquid crystal display panel) in a direction toward the panel using a prescribed pressure-bonding tool. A barrier film is sandwiched between the pressure-bonging tool and the electronic component and the flexible printed circuit board, respectively, thereby preventing, by the barrier film, the anisotropic conductive material from being adhered to the respective top surfaces of the electronic component and the flexible printed circuit board.

According to this configuration, because the barrier film is sandwiched between the pressure-bonding tool and the respective top surfaces of the electronic component and the flexible printed circuit board on which the pressing force is applied by the pressure-bonding tool, substantially no anisotropic conductive material is adhered to the respective top surfaces of the electronic component and the flexible printed circuit board. Therefore, when the anisotropic conductive material is cured, the surfaces to which the pressing force is applied do not get covered by the anisotropic conductive resin. According to this manufacturing method, even when a temperature of the electronic component and the flexible printed circuit board is increased when using the liquid crystal display device, heat can be released from the respective top surfaces of the components that are not covered with the resin to the air. Therefore, it is possible to manufacture the liquid crystal display device that can prevent damage to the components from occurring.

In the method of manufacturing the liquid crystal display device disclosed herein, the anisotropic conductive material may be constituted of a photocurable resin material and conductive particles.

According to this configuration, when the anisotropic conductive material is cured, heat is not applied. Therefore, possible defects of a polarizing plate and the liquid crystal panel due to heat can be prevented from occurring. The anisotropic conductive material can be effectively cured by radiating light (typically, ultraviolet light) to the entire anisotropic conductive material. Thus, according to the present invention, a liquid crystal display device having the anisotropic conductive resin that is manufactured by using the photocurable anisotropic conductive material can be provided. In such a liquid crystal display device, heat is not applied when mounting the electronic component and the flexible printed circuit board, making it possible to further increase the reliability thereof.

In the method of manufacturing the liquid crystal display device disclosed herein, in the applying step, an isotropic conductive material that is applied on the mounting area of the electronic component and a nearby region thereof may be different from an isotropic conductive material that is applied on the mounting area of the flexible printed circuit board and a nearby region thereof, and by continuously providing (applying) the multiple kinds of anisotropic conductive materials that are different from each other, the anisotropic conductive materials are integrally applied.

According to this configuration, in attaching (bonding) the liquid crystal display panel and the electronic component and in attaching the liquid crystal display panel and the flexible printed circuit board, the anisotropic conductive material that achieves the most appropriate adhesion strength and the like can be used. Therefore, the present invention can provide the liquid crystal display device that is manufactured by continuously providing the multiple kinds of anisotropic conductive materials that are different from each other and has therefore the multiple kinds of anisotropic conductive resins. Such a liquid crystal display device uses the anisotropic conductive materials that can achieve the most appropriate adhesion strengths and the like, thereby further increasing the reliability such as connection strength between the electronic component and the flexible printed circuit board.

### BRIEF DESCRIPTION OF THE DRAWINGS

FIG. 1 is a schematic perspective view showing a mobile phone that is provided with a liquid crystal display device according to the present invention.

FIG. 2 is a schematic plan view showing a liquid crystal panel according to an embodiment.

FIG. 3 is a cross-sectional view along the line III-III in FIG. 2.

FIG. 4 is a schematic view showing a structure of a pressure-bonding device according to an embodiment.

FIG. 5 is a flow chart for explaining a method of manufacturing the liquid crystal display device according to an embodiment.

FIG. 6 is a schematic view showing a structure of the liquid crystal panel according to an embodiment.

FIG. 7 is a schematic view showing a state where an anisotropic conductive material is applied on a prescribed location on the liquid crystal panel according to an embodiment.

FIG. 8 is a schematic view showing a state where a driver IC and a flexible printed circuit board are disposed at respective prescribed locations on the liquid crystal panel according to an embodiment.

FIG. 9 is a schematic view of the liquid crystal panel for explaining a manufacturing intermediate process of the method of manufacturing the liquid crystal display device according to an embodiment.

FIG. 10 is a schematic cross-sectional view showing a liquid crystal panel according to another embodiment.

FIG. 11 is a schematic vertical-sectional view showing a structure of a conventional liquid crystal panel.

### DETAILED DESCRIPTION OF EMBODIMENTS

Preferred embodiments of the present invention will be described below with reference to figures. Matters not specifically mentioned herein, but necessary to implement the present invention can be worked out as design matters by those skilled in the art based on conventional technologies in the field. The present invention can be implemented based on the contents disclosed herein and common technical knowledge in the field.

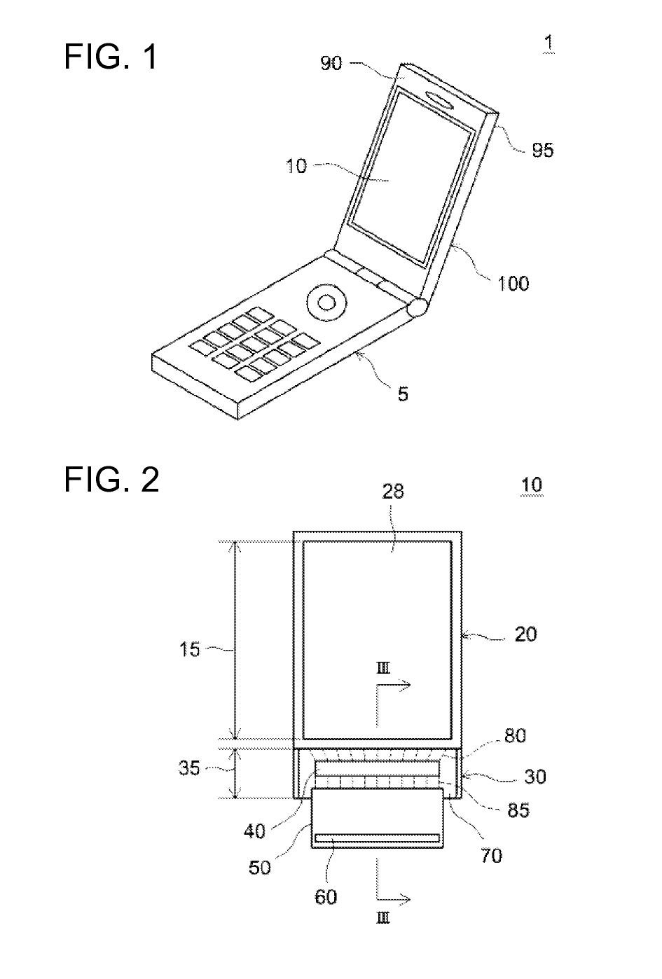

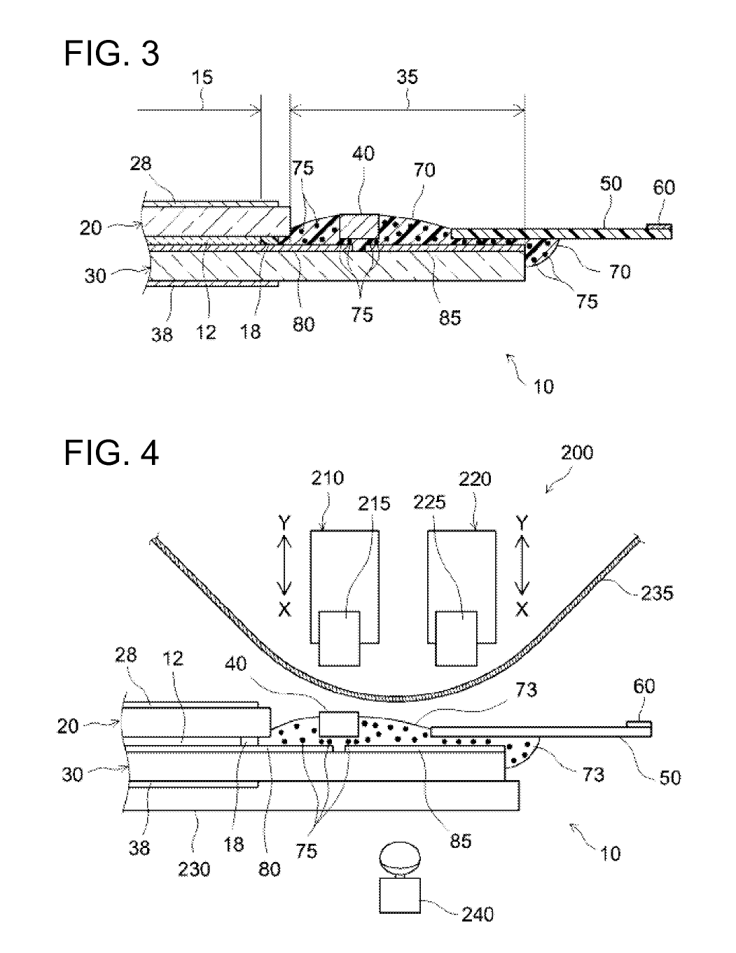

A liquid crystal display device according to a preferred embodiment (Embodiment 1) of the present invention will be described below with reference to FIGS. 1 to 3, using an active matrix (TFT-type) liquid crystal display device 100 having a liquid crystal display panel 10 (hereinafter referred to as “liquid crystal panel 10”) as a display panel as an example. FIG. 1 is a schematic perspective view showing a mobile phone 1 that is provided with the liquid crystal display device 100 according to the present invention. FIG. 2 is a schematic plan view showing the liquid crystal panel 10 according to an embodiment. FIG. 3 is a vertical-sectional view along the line III-III in FIG. 2. In the figures below, the same reference characters are given to members and portions that have the same effects, and duplicative explanations thereof may be omitted or abridged. The dimensional relationship (length, width, thickness, and the like) in the respective figures do not necessarily reflect the actual dimensional relationship accurately. In the description below, “upside” or “front side” represents a side of the liquid crystal display device 100 that faces a viewer (i.e., a liquid crystal panel side). Also, “downside” or “rear side” represents a side of the liquid crystal display device 100 that does not face a viewer (i.e., a backlight device side).

An overall configuration of the liquid crystal display device 100 will be described with reference to FIG. 1. As shown in FIG. 1, the mobile phone 1 is constituted of a top case, which is the liquid crystal display device 100, and a bottom case that has an operating unit 5. The liquid crystal display device 100 is provided with the liquid crystal panel 10 and a backlight device (not shown) that is an external light source disposed on the rear surface side of the liquid crystal panel 10. The liquid crystal panel 10 and the backlight device are attached to a bezel (frame body) 90 and the like, and are thereby held as a single component.

A structure of the liquid crystal panel 10 will be described with reference to FIGS. 2 and 3. Generally, the liquid crystal panel 10 has a rectangular shape as a whole. The liquid crystal panel 10 has a display region 15 in the center thereof, in which pixels are formed and an image is displayed. The liquid crystal panel 10 has a sandwich structure constituted of a pair of transparent glass substrates 20 and 30 that face each other and a liquid crystal layer 12 that is sealed therebetween. Of the pair of substrates 20 and 30, one on the front side is a color filer substrate (CF substrate) 20, and the other on the rear side is an array substrate 30.

On a surface of the CF substrate 20 facing the array substrate 30 in the peripheral portion, a sealing member 18 is provided so as to encircle the display region 15 sealing a liquid crystal material that contains liquid crystal molecules therebetween and thereby forming the liquid crystal layer 12. The optical characteristics of the liquid crystal material changes in accordance with an electric field applied across the substrates 20 and 30, which controls the orientation of the liquid crystal molecules. In the liquid crystal layer 12, spacers (not shown) for securing the thickness (gap) of the layer 12 are disposed, typically on multiple locations. A peripheral portion of the array substrate 30 (i.e., surface facing the CF substrate 20 but not overlapping the CF substrate 20) has a mounting area 35 to mount (attach) an electronic component 40 and the like (to be described below).

On the respective surfaces of the substrates 20 and 30 that face each other (inside surfaces), alignment films (not shown) that determine the orientation of the liquid crystal molecules are formed. On the respective surfaces thereof that do not face each other (outside surfaces), polarizing plates 28 and 38 are bonded, respectively. In a so-called normally white liquid crystal display device, respective polarizing axes of two polarizing plates 28 and 38 are arranged so as to be orthogonal to each other. In a so-called normally black liquid crystal display device, respective polarizing axes of the two polarizing plates 28 and 38 are arranged so as to be parallel to each other.

In the liquid crystal panel 10 disclosed herein, pixels for displaying an image are arranged on the front side of the array substrate 30 (side facing the liquid crystal layer 12), and a plurality of source wiring lines and gate wiring lines (not shown) to drive each of the pixels are arranged so as to form a grid pattern. In each of the grid regions encircled by such display wiring lines, a (sub) pixel electrode and a thin film transistor (TFTs) as a switching element are provided. The pixel electrodes are typically made of ITO (indium tin oxide), which is a transparent conductive material. To these pixel electrodes, a voltage corresponding to the image is supplied at a prescribed timing through the source wiring lines and the thin film transistors.

On the other hand, the CF substrate 20 is provided with color filters of R (red), G (green), and B (blue), each of which corresponds to one pixel electrode in the array substrate 30, a black matrix that divides the color filters of each color, and a common electrode (transparent electrode) that is uniformly formed on the entire surface of the color filters and the black matrix.

As shown in FIGS. 2 and 3, on the peripheral portion of the front side of the array substrate 30 (mounting area 35) in the liquid crystal panel 10, output wiring lines 80 that are electrically connected to the gate wiring lines and the source wiring lines (not shown), respectively, and input wiring lines 85 for inputting signals to the electronic component 40 are patterned and formed. The electronic component (the driver IC, for example) 40 for supplying signals to drive the liquid crystal panel 10 is attached (mounted) on the wiring lines 80 and 85 through an anisotropic conductive resin 70. More specifically, the driver IC 40 and the array substrate 30 (liquid crystal panel 10) are mechanically connected by an insulating resin contained in the anisotropic conductive resin 70. By conductive particles 75 contained in the anisotropic conductive resin 70, output electrodes (not shown) of the driver IC 40 and the output wiring lines 80 are electrically connected, and an input electrodes (not shown) of the driver IC 40 and the input wiring lines 85 are electrically connected. A side surface section in the periphery of the driver IC 40 is covered with the anisotropic conductive resin 70 (preferably, the entire side surface section in the periphery of the driver IC 40). This way, possible corrosion of the driver IC 40 that may otherwise occur due to humidity or the like can be prevented. On a top surface of the driver IC 40 (i.e., on a surface opposite to the surface that is connected to the wiring lines 80 and 85), substantially no anisotropic conductive resin 70 is provided (that is, the top surface of the driver IC 40 is not covered with the anisotropic conductive resin 70). This way, heat released from the driver IC 40 to the air is not blocked, thereby preventing damage to the driver IC 40 due to an increase in temperature of the driver IC 40. In the present embodiment, the single electronic component (driver IC) 40 is attached (mounted) on the liquid crystal panel 10, but a plurality of electronic components may be attached thereon.

As shown in FIGS. 2 and 3, on the outer side with respect to the driver IC 40 in the peripheral portion of the array substrate 40 (mounting area 35) (mounting area of the flexible printed circuit board, which is located a prescribed distance away from the mounting area of the driver IC 40 in a direction toward the outer circumference (in a direction away from the display region 15)), external terminals (not shown) of a flexible printed circuit (FPC) board 50 are attached on the input wiring lines 85 through the anisotropic conductive resin 70. The anisotropic conductive resin 70 is integrally provided on a region that covers the mounting area of the driver IC 40 to the mounting area of the FPC 50. (In the present embodiment, the anisotropic conductive resin 70 is provided so as to cover a region from an area where the sealing member 18 is formed to the mounting area of the FPC 50, which covers almost the entire surface of the mounting area 35 of the array substrate 30.) Here, on the top surface of the FPC 50 (i.e., on a surface opposite to the surface that is connected to the input wiring lines 85), substantially no anisotropic conductive resin 70 is provided (formed). This way, heat released from the FPC 50 to the air is not blocked, thereby preventing damage to the component due to an increase in the temperature.

As shown in FIG. 3, the anisotropic conductive resin 70 is integrally provided on a region from the area where the sealing member 18 is formed to the mounting area of the FPC 50. Further, the anisotropic conductive resin 70 has a portion that is integrally formed therewith, extending beyond the mounting area of the FPC 50 and protruding outwardly from the outer edge of the liquid crystal panel 10 (the outer edge of the array substrate 30). The outer edge of the array substrate 30 (typically, a sidewall of the outer edge of the array substrate 30) and an area on the rear side of the FPC 50 (i.e., a portion that protrudes outwardly from the outer edge of the array substrate 30) are fixed to each other by the anisotropic conductive resin 70 that protrudes outwardly from the outer edge of the array substrate 30. This way, the adhesion strength between the array substrate 30 and the FPC 50 at the outer edge of the array substrate 30 can be increased.

On an end of the FPC 50, a printed circuit board (PCB) 60 is attached. On the PCB 60, controllers (controlling circuits) that control the driver IC (chip) 40, other electronic components, and the like are mounted.

As shown in FIGS. 2 and 3, on a region where the driver IC 40 and the FPC 50 are not mounted, the anisotropic conductive resin 70 is integrally provided so as to cover the respective surfaces of the wiring lines 80 and 85 that are patterned and formed on the surface of the array substrate 30. Therefore, respective connecting portions of the driver IC 40 and the FPC 50 and the wiring lines 80 and 85 can be protected from corrosion due to humidity or the like.

In the present embodiment, the driver IC 40 is mounted together with the FPC 50 on the peripheral portion of the liquid crystal panel 10 (mounting area 35), but in addition to the driver IC 40, chip parts such as a capacitor, a resistor, and a diode may be mounted on the liquid crystal panel 10.

The anisotropic conductive resin 70 can be suitably formed by using an anisotropic conductive material made of a material that has the following features: the material can be suitably adhered to the driver IC 40, FPC 50, and the array substrate 30 (including the wiring lines 80 and 85); and the material has conductivity at a connecting portion of the driver IC 40 and the array substrate 30 and at a connecting portion of the FPC 50 and the array substrate 30, and has an insulating property at other portions. For such a material, a material made of an insulating resin having conductive particles dispersed therein can be used without special limitations. For the insulating resin, a thermosetting resin material and a photocurable resin material can be given as examples. It is preferable to use a photocurable resin material, especially an UV-curable resin material. For the conductive particles, conductive particles that exhibit conductivity in the vertical direction by pressure bonding (pressing) and that exhibit an insulating property in the horizontal direction can be given as an example. For such conductive particles, nickel or the like that is coated with gold and that is further coated with an insulating layer on the outermost layer can be given as an example. Alternatively, conductive particles that are not coated with the insulating layer on the outermost layer may be used.

As shown in FIG. 1, in the liquid crystal display device 100 that has the liquid crystal panel 10 on which the driver IC 40 and the FPC 50 are attached (mounted) as described above, on the front side of the liquid crystal panel 10, the bezel (frame body) 90 is attached. On the rear side of the liquid crystal panel 10, a case 95 is attached. The bezel 90 and the case 95 hold the liquid crystal panel 10 by sandwiching the both surfaces thereof. In the case 95, a backlight device (not shown) that is constituted of a light guide plate, a reflective sheet, and the like is attached on the rear side of the polarizing plate 38 of the liquid crystal panel 10.

The backlight device is constituted of the light guide plate, the reflective sheet, and the light source. The reflective sheet is disposed below the light guide plate. The light source is disposed on an end surface of the light guide plate, and is provided with a plurality of LEDs that are point light sources, for example. Light emitted from each of the LEDs enters the light guide plate, and changes the travel direction thereof by repeatedly reflecting off the top and bottom surfaces of the light guide plate. Thereafter, the light is output to the array substrate 30 from the top surface of the light guide plate, and travels through the liquid crystal panel 10 (display region 15).

Next, a pressure-bonding device 200 that is used when manufacturing the liquid crystal display device according to the present embodiment will be described. FIG. 4 is a schematic view showing a structure of the pressure-bonding device 200 according to the present embodiment. Generally, the pressure-bonding device 200 is provided with a pressure-bonding tool 210 for the driver IC (hereinafter referred to as “IC pressure-bonding tool 210”), a pressure-bonding tool 220 for the flexible printed circuit board (hereinafter referred to as “FPC pressure-bonding tool 220”), and a panel support 230 for supporting the liquid crystal panel 10. The IC pressure-bonding tool 210 bonds, by pressure, the driver IC 40 to the wiring lines 80 and 85 (mounting area) that are formed on the array substrate 30. The FPC pressure-bonding tool 220 bonds, by pressure, the FPC 50 to the input wiring line 85 (mounting area) that is formed on the array substrate 30. The IC pressure-bonding tool 210 and the FPC pressure-bonding tool 220 are respectively provided with air cylinders and the like (not shown). The air cylinders and the like enable the pressure-bonding tools to independently move in the vertical directions (upward movement in a direction shown by the arrow Y, and downward movement in a direction shown by the arrow X).

The IC pressure-bonding tool 210 is provided with a pressure-bonding head 215 for the IC. Similarly, the FPC pressure-bonding tool 220 is provided with an FPC pressure-bonding head 225. The pressure-bonding tools 210 and 220 are provided with a controlling unit that controls each of the pressure-bonding heads 215 and 225. The controlling unit can adjust the positions of the pressure-bonding heads 215 and 225, respectively, when the pressure-bonding heads are moved, and can control the temperature of the respective pressure-bonding heads (the controlling unit can heat the pressure-bonding heads to about 200 to 400° C., for example). Further, the controlling unit can control a pressing force to be applied on the respective top surfaces (in other words, surfaces opposite to the surfaces that are in contact with the array substrate 30) of the driver IC 40 and the FPC 50.

The pressure-bonding device 200 is provided with a sheet-like barrier film 235 between the respective pressure-bonding tools 210 and 220 and the panel support 230. When the pressure-bonding heads 215 and 225 are respectively in contact with the top surfaces of the driver IC 40 and the FPC 50, and apply a prescribed pressing force thereon, the barrier film 235 is sandwiched between a pressure-bonding surface of the IC pressure-bonding head 215 (a surface that faces the top surface of the driver IC 40) and the top surface of the driver IC 40. Also, the barrier film 235 is sandwiched between a pressure-bonding surface of the FPC pressure-bonding head 225 (a surface that faces the top surface of the FPC 50) and the top surface of the FPC 50. This way, it is possible to prevent an anisotropic conductive material 73 from being adhered to the respective top surfaces of the driver IC 40 and the FPC 50. Further, because the anisotropic conductive material 73 is not adhered to the respective pressure-bonding surfaces of the pressure-bonding heads 215 and 220, the respective pressure-bonding surfaces of the pressure-bonding heads 215 and 220 can be maintained flat. By sandwiching the barrier film 235 therebetween, it is possible to apply a uniform pressing force on the driver IC 40 and the like. There is no special limitation on the material that constitutes the barrier film 235 as long as the anisotropic conductive material 73 is not adhered to the material. For such a material, a silicon rubber and a fluorine resin such as polytetrafluoroethylene can be given as examples.

It is preferable that the pressure-bonding device 200 be provided with a UV-radiating device 240 below the panel support 230. The radiating device 240 is typically disposed immediately below the anisotropic conductive material 73 that is continuously applied on the liquid crystal panel 10 (array substrate 30). The panel support 230 is made of a material that allows UV light to pass through.

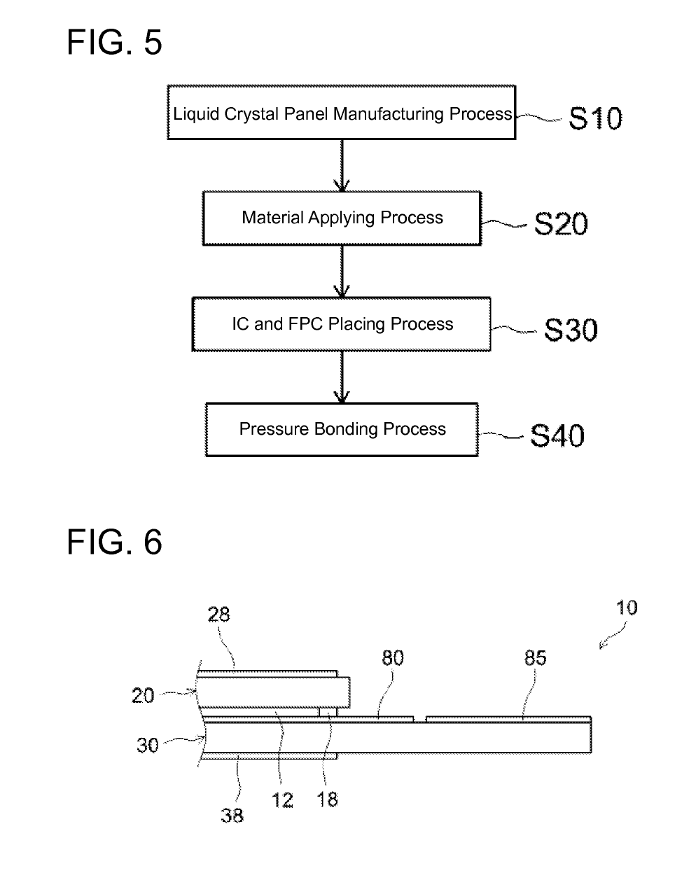

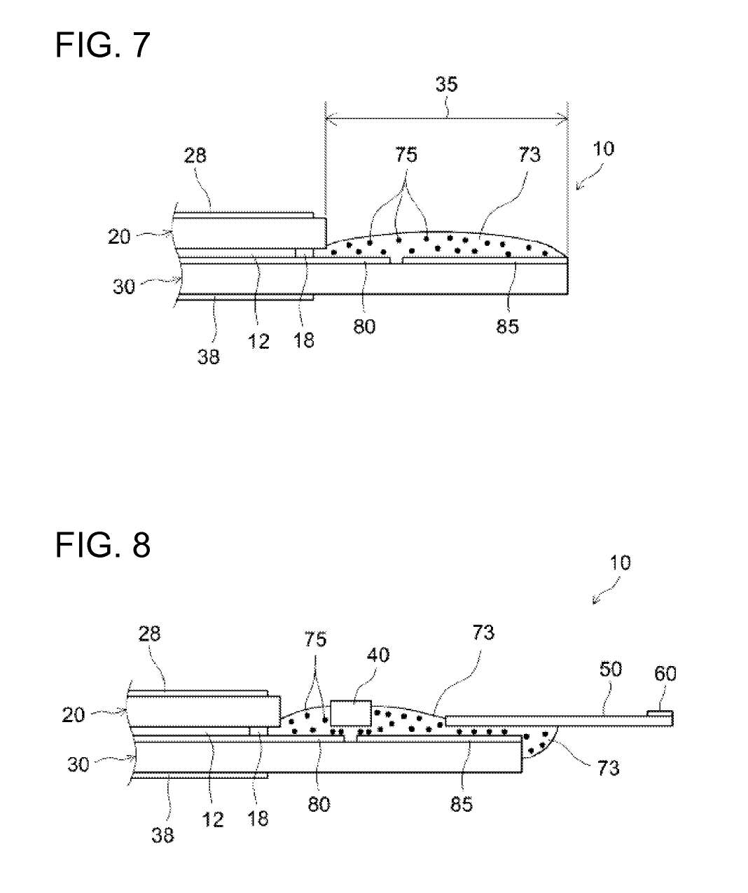

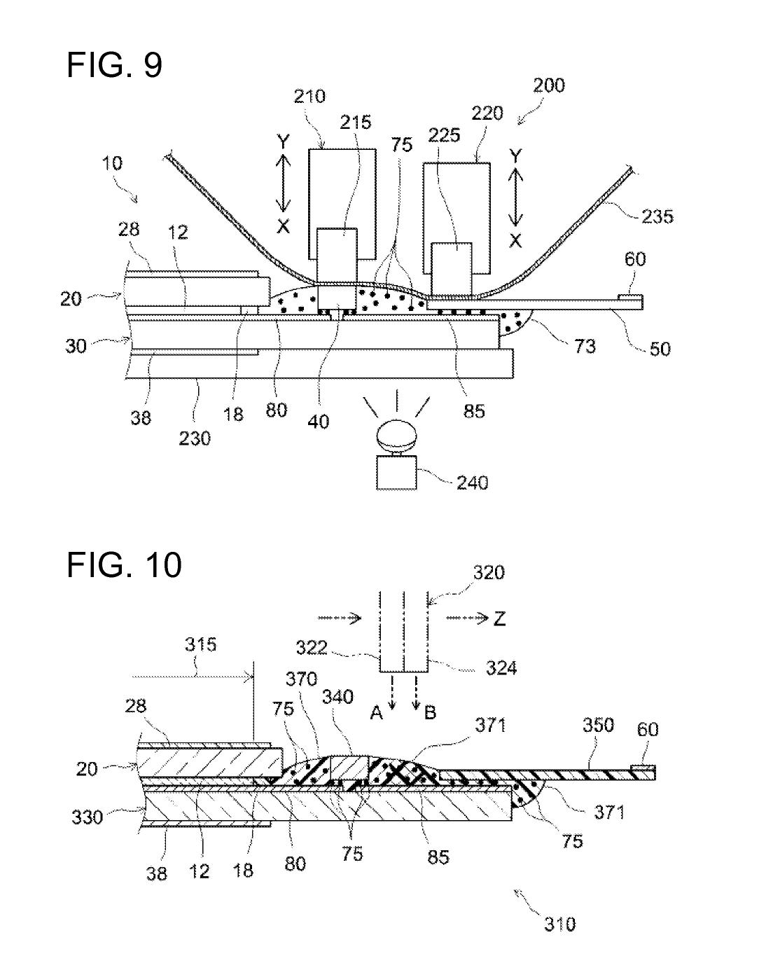

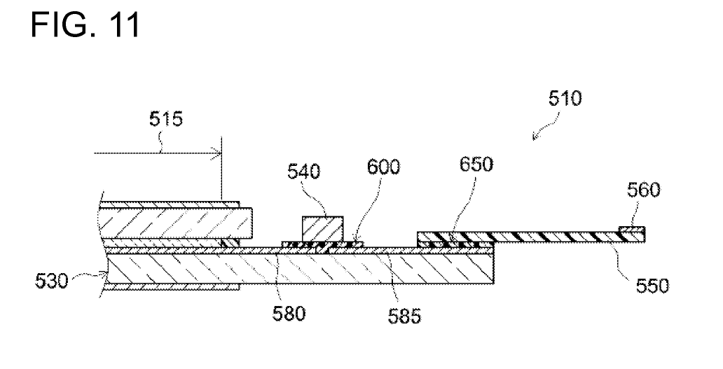

Next, an example of a method of manufacturing the liquid crystal display device 100 according to the present embodiment will be described with reference to FIGS. 5 to 9. FIG. 5 is a flow chart for explaining a method of manufacturing the liquid crystal display device 100 according to the present embodiment. FIG. 6 is a schematic view showing a structure of the liquid crystal panel 10 according to the present embodiment. FIG. 7 is a schematic view showing a state where the anisotropic conductive material 73 is applied on a prescribed location on the liquid crystal panel 10. FIG. 8 is a schematic view showing a state where the driver IC 40 and the flexible printed circuit board 50 are disposed at respective prescribed locations on the liquid crystal panel 10 according to the present embodiment. FIG. 9 is a schematic view of the liquid crystal panel 10 for explaining an intermediate step in the method of manufacturing the liquid crystal display device 100 according to the present embodiment.

As shown in FIGS. 5 and 6, the manufacturing method according to the present embodiment includes manufacturing the liquid crystal panel 10 (liquid crystal panel manufacturing step S10). First, the CF substrate 20 and the array substrate 30 are manufactured. Because the method of manufacturing the CF substrate 20 and the array substrate 30 is the same as the conventional method, detailed descriptions thereof will not be repeated. On a prescribed location on one of the pair of substrates 20 and 30, a sealing material is provided by a dispenser method, for example, and on a region that is encircled by the sealing material, a liquid crystal material is dripped by the dispenser method, for example. Thereafter, the CF substrate 20 and the array substrate 30 are bonded to each other under a vacuum environment such that respective display regions thereof are overlapped with each other. Next, the sealing material is cured to form the sealing member 18, and the liquid crystal panel 10 provided with the liquid crystal layer 12 that is formed between the CF substrate 20 and the array substrate 30 is fabricated. Thereafter, on both of the surfaces of the liquid crystal panel 10 (i.e., the front surface of the CF substrate 20 and the rear surface of the array substrate 30), the polarizing plates 28 and 38 are attached, respectively.

As shown in FIGS. 5 and 7, the method according to the present embodiment includes applying (providing) the anisotropic conductive material 73 on a prescribed location (the mounting area 35 on the array substrate 30) on the liquid crystal panel 10 that is obtained by performing the above step (a material applying process S20). The anisotropic conductive material (constituted of a UV-curable resin material and conductive particles, for example) 73 is continuously applied by the dispenser method, for example, on a region from the mounting area of the driver IC (electronic component) 40 to the mounting area of the FPC 50 on the array substrate 30. In the present embodiment, the anisotropic conductive material 73 is applied on the entire array substrate 30 covering the output wiring lines 80 and the input wiring lines 85 that are patterned and formed on the array substrate 30 (i.e., on a region from an area where the sealing member 18 is formed to the mounting area 35). In an IC and FPC placing process, which will be described below, it is preferable that, in placing the FPC 50 on the FPC mounting area on the array substrate 30, the anisotropic conductive material 73 that is continuously applied on the array substrate 30 be applied in the amount that allows part of the anisotropic conductive material 73 to extend beyond the FPC mounting area and protrude from the outer edge of the array substrate 30 (liquid crystal panel 10).

Next, as shown in FIGS. 5 and 8, in the method according to the present embodiment, the driver IC 40 is aligned and placed in the mounting area of the driver IC 40 on the array substrate 30 (liquid crystal panel 10) on which the anisotropic conductive material 73 is continuously applied, and the FPC 50 is aligned and placed in the mounting area of the FPC 50, and placing the FPC 50 (IC and FPC placing step S30). The driver IC 40 is placed on the array substrate 30 such that the side surface section in the periphery of the driver IC 40 is covered with the anisotropic conductive material 73. By placing the FPC 50 on the mounting area, part of the anisotropic conductive material 73 that is continuously applied on the array substrate 30 protrudes from the outer edge of the array substrate 30. As a result, the anisotropic conductive material 73 is provided so as to bridge over the outer edge of the array substrate 30 (typically, an outer edge surface of the array substrate 30) to the rear surface of the FPC 50. In the present embodiment, the FPC having a printed circuit board 60 attached on the end thereof in advance was used.

As shown in FIGS. 5 and 9, the method according to the present embodiment includes curing the anisotropic conductive material 73 while applying a prescribed pressing force(s) on the driver IC 40 and the FPC 50 that are placed on the array substrate 30 in the above step (pressure bonding step S40). That is, the anisotropic conductive material 73 is cured using the pressure-bonding device 200.

As shown in FIG. 9, the array substrate 30 of the liquid crystal panel 10 is fixed on the panel support 230 of the pressure-bonding device 200 in a manner that the rear surface of the array substrate 30 is in contact with the panel support 230. The respective locations of the pressure-bonding tools 210 and 220 are adjusted such that a pressure-bonding surface of the IC pressure-bonding head 215 is located immediately above the driver IC 40 and the FPC pressure-bonding head 225 is located immediately above the FPC 50 (the FPC mounting area on the array substrate 30).

Next, by the air cylinders (not shown), the IC pressure-bonding tool 210 is moved downward in the direction shown by the arrow X, and the IC pressure-bonding head 215 is pressed on the top surface of the driver IC 40 at a normal temperature (in other words, the IC pressure-bonding head 215 is not heated) while sandwiching the barrier film 235 therebetween. In the same manner, the FPC pressure-bonding tool 220 is moved downward in the direction shown by the arrow X, and the FPC pressure-bonding head 225 is pressed on the top surface of the FPC 50 (portion that is opposite to the portion that is in contact with the array substrate 30) at a normal temperature while sandwiching the barrier film 235 therebetween. Because the pressure-bonding tools 210 and 220 according to the present embodiment can independently move in the vertical direction, the present embodiment can be used even when the respective heights from the surface of the array substrate 30 to the driver IC 40 and to the FPC 50 are different.

While a uniform pressing force is applied on the respective top surfaces of the driver IC 40 and the FPC 50 (the pressure-bonding heads 215 and 225 are not heated and held at a normal temperature), the UV-radiating device 240 is operated, curing the anisotropic conductive material 73 by radiating the UV light thereto. The UV light that is emitted from the UV-radiating device 240 transmits through the panel support 230 and the array substrate 30, and radiates the entire anisotropic conductive material 73.

This way, as shown in FIG. 3, the anisotropic conductive material 73 is cured, and the driver IC 40 and the FPC 50 are thereby attached (mounted) onto the array substrate 30 (liquid crystal panel 10) by the anisotropic conductive resin 70. At this time, by the conductive particles 75 that are sandwiched between the driver IC 40 and the wiring lines (the output wiring lines 80 and the input wiring lines 85) that are formed on the array substrate 30, the driver IC 40 and the wiring lines 80 and 85 are electrically connected. On the other hand, by the conductive particles 75 that are sandwiched between the FPC 50 and the input wiring lines 85 formed on the array substrate 30, the FPC 50 and the wiring lines 85 are electrically connected. The side surface section in the periphery of the driver IC 40 and the wiring lines 80 and 85 that are patterned and formed on the surface of the array substrate 30 are covered with the anisotropic conductive resin 70, and are thereby protected from possible corrosion or the like due to humidity or the like. Further, when the anisotropic conductive material 73 that protrudes from the outer edge of the array substrate 30 is cured, the rear surface of the FPC 50 and the outer edge of the array substrate 30 can be fixed to each other. As a result, the adhesion strength between the FPC 50 and the liquid crystal panel 10 (typically, the array substrate 30) can be increased.

The above embodiment described an example where the anisotropic conductive material is made of the UV-cured resin material, but the anisotropic conductive material may be made of a thermosetting resin material. In such an example, the pressure-bonding heads 215 and 225 are pressed on the respective top surfaces of the driver IC 40 and the FPC 50 sandwiching the barrier film 235 therebetween, and by heating the pressure-bonding heads 215 and 225 to about 200° C. to 400° C. while applying a uniform pressing force(s) on the respective top surfaces of the driver IC 40 and the FPC 50, the anisotropic conductive material can be cured.

As described above, the driver IC (electronic component) 40 and the FPC 50 are attached on the liquid crystal panel 10, and thereafter, on the rear side of the polarizing plate 38 of the liquid crystal panel 10, the backlight device that is constituted of the light guide plate, the reflective sheet, and the like are attached. Next, on the front side (i.e., on the CF substrate 20 side) and on the rear side (on the array substrate 30 side, which is the outer side of the backlight device) of the liquid crystal panel 10, the bezel 90 and the case 95 are disposed, respectively, to hold the liquid crystal panel 10, thereby forming the liquid crystal display device 100.

In the above embodiments, one kind of anisotropic conductive material is continuously applied, but the present invention is not limited to such. A preferred example in case of successively applying multiple kinds of anisotropic conductive materials will be described below with reference to figures. FIG. 10 is a schematic cross-sectional view showing a liquid crystal panel 310 according to Embodiment 2.

As shown in FIG. 10, in the liquid crystal panel 310 according to the present embodiment, anisotropic conductive resins 370 and 371 that have different characteristics are continuously disposed and integrally formed. (On the border of the anisotropic conductive resins 370 and 371, the respective resins are mixed with each other.) A driver IC 340 and an array substrate 330 are connected by the anisotropic conductive resin 370, and a flexible printed circuit board 350 and the array substrate 330 are connected by the anisotropic conductive resin 371. As the anisotropic conductive resins 370 and 371, any resins can be used without limitations by changing the property/conditions (compositions and the like) thereof in accordance with the characteristics of the members to be connected.

By using a paste application device 320 that is shown by the two-dot chain line in FIG. 10, for example, multiple kinds of anisotropic conductive materials (made of a UV-curable resin material and conductive particles, for example) that have different characteristics from each other are applied on the liquid crystal panel 310 (array substrate 330). The paste application device 320 is provided with a plurality of paste supplying units 322 and 324. By moving the paste application device 320 in a direction shown by the arrow Z in FIG. 10, the paste application device 320 applies a first anisotropic conductive material A (a material having appropriate characteristics for bonding the driver IC 340 to the array substrate 330) from a display region 315 to a mounting area of the driver IC 340 and a nearby region thereof through the paste supplying unit 322, and also applies a second anisotropic conductive material B (a material having appropriate characteristics for bonding the flexible printed circuit board 350 and the array substrate 330) from a region near the mounting area of the flexible printed circuit board 350 to the mounting area through the paste supplying unit 324. For such an application device, an application device having the same configuration as a conventional device can be used without special limitations, and therefore, more detailed descriptions is omitted.

According to the present embodiment, in connecting the array substrate 330 to the driver IC 340 and in connecting the array substrate 330 to the flexible printed circuit board 350, anisotropic conductive materials having compositions most suited for respective connections can be used, thereby providing improved connections.

Specific examples of the present invention were described above in detail with reference to the figures, but these specific examples are illustrative, and not limiting the scope of the claims. The technical scope defined by the claims includes various modifications of the specific examples described above.

In the above embodiment, the single electronic component (driver IC) and the single flexible printed circuit board are attached (mounted) on the liquid crystal panel, but the present invention is not limited to such. A plurality of electronic components and/or a plurality of flexible printed circuit boards may be attached on the liquid crystal panel.

### INDUSTRIAL APPLICABILITY

According to the liquid crystal display device provided by the present invention, the electronic component and the flexible printed circuit board are mounted on the liquid crystal display panel by the anisotropic conductive resin that is integrally provided at least from the mounting area of the electronic component to the mounting area of the flexible printed circuit board. Further, the side surface of the electronic component is covered with the anisotropic conductive resin. Therefore, the respective connecting portions of the electronic component and the flexible printed circuit board and the electronic component itself are prevented from corroding due to humidity or the like.

### DESCRIPTION OF REFERENCE CHARACTERS

1 mobile phone
5 operating unit
10 liquid crystal panel (liquid crystal display panel)
12 liquid crystal layer
15 display region
18 sealing member
20 color filter substrate (CF substrate)
28 polarizing plate
30 array substrate
35 mounting area
38 polarizing plate
40 driver IC (electronic component)
50 flexible printed circuit board (FPC)
60 printed circuit board (PCB)
70 anisotropic conductive resin
73 anisotropic conductive material
75 conductive particle
80 output wiring line
85 input wiring line
90 bezel
95 case
100 liquid crystal display device
200 pressure-bonding device
210 pressure-bonding tool for driver IC (IC pressure-bonding tool)
215 IC pressure-bonding head
220 pressure-bonding tool for flexible printed circuit board (FPC pressure-bonding tool)
225 FPC pressure-bonding head
230 panel support
235 barrier film
240 UV-radiating device
310 liquid crystal panel
315 display region
320 paste application device
322, 324 paste supplying unit
330 array substrate
340 driver IC
350 flexible printed circuit board
370, 371 anisotropic conductive resin
510 liquid crystal panel
515 image display region
530 array substrate
540 driver IC
550 flexible printed circuit board (FPC)
560 printed circuit board
580, 585 wiring line
600, 650 anisotropic conductive film (ACF)

1. A liquid crystal display device, comprising:
a liquid crystal display panel;
at least one electronic component mounted on the liquid crystal display panel in a peripheral portion of the panel;
a flexible printed circuit board disposed in the peripheral portion of the liquid crystal display panel on an outer side with respect to the electronic component; and
an anisotropic conductive resin integrally provided on a region in the peripheral portion of the liquid crystal display panel covering at least a mounting area of the electronic component to a mounting area of the flexible printed circuit board, the anisotropic conductive resin being made of an insulating resin having conductive particles dispersed and mixed therein,
wherein the electronic component and the flexible printed circuit board are electrically connected, respectively, to the liquid crystal display panel through the anisotropic conductive resin, and
wherein a side surface section in a periphery of the electronic component is covered with the anisotropic conductive resin.

2. The liquid crystal display device according to claim 1, wherein the anisotropic conductive resin that is integrally provided extends beyond the mounting area of the flexible printed circuit board and protrudes outwardly from an outer edge of the liquid crystal display panel, and
wherein, by the resin protruding outwardly from the outer edge, the outer edge of the panel and a portion of the flexible printed circuit board that protrudes outwardly from the outer edge of the panel are fixed to each other.

3. The liquid crystal display device according to claim 1, wherein the electronic component and the flexible printed circuit board have substantially no anisotropic conductive resin on respective surfaces opposite to portions thereof that are electrically connected to the liquid crystal display panel.

4. The liquid crystal display device according to claim 1, wherein the anisotropic conductive resin includes a photocurable resin and conductive particles.

5. The liquid crystal display device according to claim 1, wherein an anisotropic conductive resin that is provided on the mounting area of the electronic component and a nearby region thereof is different from an anisotropic conductive resin that is provided on the mounting area of the flexible printed circuit board and a nearby region thereof.

6. A method of manufacturing a liquid crystal display device that comprises:
a liquid crystal display panel;
at least one electronic component mounted on the liquid crystal display panel in a peripheral portion of the panel; and
a flexible printed circuit board disposed in the peripheral portion of the liquid crystal display panel on an outer side with respect to the electronic component, the method comprising:
applying integrally an anisotropic conductive material on a region in the peripheral portion of the liquid crystal display panel covering at least a mounting area of the electronic component to a mounting area of the flexible printed circuit board, the anisotropic conductive material being made of an insulating resin material having conductive particles dispersed and mixed therein;
placing the electronic component on the mounting area of the electronic component in a region where the anisotropic conductive material is integrally applied such that a side surface portion in a periphery of the electronic component is covered with the anisotropic conductive material, and placing the flexible printed circuit board on the mounting area of the flexible printed circuit board, which is located a prescribed distance away from a location where the electronic component is placed in a direction toward an outer circumference; and
curing the anisotropic conductive material while applying a prescribed pressing force on the electronic component and the flexible printed circuit board in a direction toward the panel.

7. The manufacturing method according to claim 6, wherein
in the applying step, the anisotropic conductive material is applied in an amount that allows part of the anisotropic conductive material to extend beyond the mounting area of the flexible printed circuit board and protrude from an outer edge of the panel when the flexible printed circuit board is placed; and
in the curing step, curing the anisotropic conductive material that protrudes from the outer edge of the panel and thereby fixing the flexible printed circuit board and the outer edge of the panel to each other.

8. The manufacturing method according to claim 6, wherein, in the curing step, the pressing force is applied by pressing respective top surfaces of the electronic component and the flexible printed circuit board in a direction toward the panel using a prescribed pressure-bonding tool, and a barrier film is sandwiched between the pressure-bonging tool and the electronic component and the flexible printed circuit board, thereby preventing, by the barrier film, the anisotropic conductive material from being adhered to the respective top surfaces of the electronic component and the flexible printed circuit board.

9. The manufacturing method according to claim 6, wherein the anisotropic conductive material includes a photocurable resin material and conductive particles.

10. The manufacturing method according to claim 6, wherein, in the applying step, an isotropic conductive material that is applied on the mounting area of the electronic component and a nearby region thereof is different from an isotropic conductive material that is applied on the mounting area of the flexible printed circuit board and a nearby region thereof; and
wherein, in said integral application of the anisotropic conductive materials, these mutually different anisotropic conductive materials are successively provided.
